(19) United States
(12) Patent Application Publication
(10) Pub. No.: US 2026/0312560 A1
(43) Pub. Date: Oct. 8, 2026

(54) METHOD FOR PRODUCING A DONOR SUBSTRATE FOR TRANSFERRING A PIEZOELECTRIC LAYER ONTO A CARRIER SUBSTRATE

(71) Applicant: Soitec, BERNIN (FR)

(72) Inventors: Cédric Charles-Alfred, BERNIN (FR); Raphaël Caulmilone, BERNIN (FR); Maxime Veilly, BERNIN (FR); Stéphane Thieffry, BERNIN (FR); Rénald Guerin, BERNIN (FR)

(21) Appl. No.: 19/480,679

(22) PCT Filed: Jun. 25, 2024
(86) PCT No.: PCT/EP2024/067730

§ 371 Date: Oct. 31, 2025

(30) Foreign Application Priority Data
Jun. 30, 2023 (FR) 2307030

(51) Int. Cl. H03H 3/02; H03H 9/17; H10N 30/073

(52) U.S. Cl. CPC H03H 3/02; H03H 9/175; H10N 30/073

(57) ABSTRACT

A method of fabricating a donor substrate for transferring a piezoelectric layer to a carrier substrate includes the following successive steps:
(a) providing a piezoelectric substrate and a handle substrate,
(b) depositing a photopolymerizable adhesive layer on a main face of the handle substrate or of the piezoelectric substrate,
(c) bonding the piezoelectric substrate with the handle substrate via the adhesive layer to form a heterostructure,
(d) irradiating the heterostructure with a light flux to polymerize the adhesive layer,
(e) heat treating the irradiated heterostructure,
(f) thinning the piezoelectric substrate from the side thereof opposite the handle substrate, so as to form the donor substrate.

### CROSS-REFERENCE TO RELATED APPLICATIONS

This application is a national phase entry under 35 U.S.C. § 371 of International Patent Application PCT/EP2024/067730, filed Jun. 25, 2024, designating the United States of America and published as International Patent Publication WO 2025/003091 A1 on Jan. 2, 2025, which claims the benefit under Article 8 of the Patent Cooperation Treaty of French Patent Application Serial No. FR2307030, filed Jun. 30, 2023.

### TECHNICAL FIELD

The present disclosure relates to a process for fabricating a donor substrate for the transfer of a piezoelectric layer to a carrier substrate, to a process for the transfer of a piezoelectric layer to such a carrier substrate and to a process for fabricating a bulk acoustic wave device comprising such a transfer. The present disclosure lastly relates to a donor substrate for the transfer of a piezoelectric layer.

### BACKGROUND

The transfer of an active layer, i.e., a layer intended for the formation of components for electronic, optical or opto-electronic devices, to a carrier substrate by means of an electrically-insulating layer, is widely used in the microelectronics industry.

One example of an active-layer transfer process that is well known is the Smart Cut™ process. This process comprises forming a weakened zone by implanting atomic species into the donor substrate, in order to delimit a layer of interest to be transferred, bonding the donor substrate to the carrier substrate, and then detaching the donor substrate along the weakened zone, so as to transfer the layer of interest to the carrier substrate.

In certain situations, it is not possible to bond the donor substrate directly to the carrier substrate. More particularly, the bonding of the donor substrate to the carrier substrate may be achieved via silicon oxide layers formed beforehand on the surface of each of the two substrates. To strengthen the oxide-oxide bonding between the piezoelectric substrate and the carrier substrate, it is known practice to carry out, after bonding, a consolidation anneal. The consolidation anneal is typically carried out at a temperature of between 100° C. and 300° C.

The Smart Cut™ process may also require an anneal to be performed in order to detach the layer of interest to be transferred, in a temperature range of from 100° C. to 600° C.

When the donor substrate and the donor substrate have different coefficients of thermal expansion—which is the case, for example, between a donor substrate made of a piezoelectric material and a carrier substrate made of silicon—such anneals result in significant deformation of the assembly of the two substrates, which is detrimental to the transfer process in that it may lead to the substrates breaking.

To minimize such deformation, it is possible to form an intermediate substrate called a pseudo-donor substrate, in which the donor substrate is joined to a temporary handle substrate.

The process for fabricating the pseudo-donor substrate generally comprises a number of steps. Thus, a thick layer made of a piezoelectric material is bonded to the handle substrate, for example, a silicon substrate. Next, the layer made of piezoelectric material is thinned and optionally trimmed. Lastly, the free surface of the thinned layer made of piezoelectric material is polished, for example, in a chemical-mechanical polishing (CMP) process and optionally covered with a thin oxide layer so as to carry out the abovementioned oxide-oxide bonding with the carrier substrate.

The bonding of the piezoelectric substrate and the handle substrate to form the pseudo-donor substrate may be achieved via oxide layers formed beforehand on the surface of each of the two substrates. However, depositing an oxide layer on the piezoelectric substrate causes the piezoelectric substrate to bow substantially, which is incompatible with the later steps of the process. Furthermore, the formation of oxide layers required for the bonding is lengthy and expensive. Lastly, as mentioned above, the heterostructure cannot undergo the consolidating anneal because of the differences in coefficients of thermal expansion between the piezoelectric substrate and the handle substrate. However, in the absence of the consolidating anneal, the bonding energy of the oxide layers of the two substrates remains very low, such that the mechanical strength of the pseudo-donor substrate is insufficient. Consequently, a break at the bonding interface may occur during the step of thinning the thick piezoelectric substrate.

One advantageous alternative to oxide-oxide bonding for assembling the heterostructure constituting the pseudo-donor substrate is the use of a photopolymerizable adhesive layer: the photopolymerizable adhesive layer is deposited on one face of the handle substrate or of the piezoelectric material layer, the handle substrate is bonded to the piezoelectric material layer via the adhesive layer and then the heterostructure thus formed is irradiated with a light flux so as to polymerize the adhesive layer.

The photopolymerized adhesive layer gives the pseudo-donor substrate good mechanical strength. It also makes it possible to dispense with the process steps carried out at high temperature that are liable to cause significant bowing of the substrate. Furthermore, the formation of such an adhesive layer is very straightforward to implement and is inexpensive.

After bonding, the pseudo-donor substrate and the carrier substrate, the piezoelectric substrate is held between the handle substrate and the carrier substrate. The choice of materials and thicknesses of the handle substrate and of the carrier substrate makes it possible to ensure a certain symmetry of the thermal expansion coefficients, and thus to minimize the deformation of the assembly during the application of heat treatments.

However, when implementing such a process for fabricating a structure of piezoelectric-on-insulator type, the applicants have observed defects in the bonding between the pseudo-donor substrate and the carrier substrate, in the form of voids, referred to as “edge bonding voids,” in which bonding does not occur at the periphery of the substrates.

### BRIEF SUMMARY

One objective of the present disclosure is to design a pseudo-donor substrate for transferring a portion of a thinned piezoelectric layer onto a carrier substrate, the pseudo-donor substrate being formed by joining the thinned piezoelectric layer and a handle substrate by means of a polymer adhesive layer, which makes it possible to improve the quality of the bonding between the thinned piezoelectric layer of the pseudo-donor substrate and the carrier substrate.

To this end, the present disclosure provides a process for fabricating a donor substrate for transferring a piezoelectric layer to a carrier substrate, comprising the following successive steps:
(a) providing a piezoelectric substrate and a handle substrate,
(b) depositing a photopolymerizable adhesive layer on a main face of the handle substrate or of the piezoelectric substrate,
(c) bonding the piezoelectric substrate with the handle substrate via the adhesive layer to form a heterostructure,
(d) irradiating the heterostructure with a light flux in order to polymerize the adhesive layer,
(e) heat treating the irradiated heterostructure, and
(f) thinning the piezoelectric substrate from the side thereof opposite the handle substrate, so as to form the donor substrate.

The heat treatment of the heterostructure comprising the thick piezoelectric layer, the photopolymerized adhesive layer and the handle substrate makes possible to increase the stiffness of the photopolymerized adhesive layer. The resulting pseudo-donor substrate has a better mechanical strength, is less sensitive to vibrations generated during the thinning step, which makes it possible to obtain a free surface of the thinned piezoelectric layer that is flatter, in particular, at the periphery of the pseudo-donor substrate, so that the quality of the bonding to the carrier substrate is improved.

According to other optional features of the process for fabricating a donor substrate for the transfer of a piezoelectric layer onto a carrier substrate, taken alone or in combination when this is technically possible:
the process of fabricating a donor substrate further comprises a step (g) of chemical-mechanical polishing of the free surface of the thinned piezoelectric substrate;
the heat treatment (e) is carried out so as to increase the degree of crosslinking of the polymer in the photopolymerized adhesive layer and/or the stiffness of the photopolymerized adhesive layer;
the heat treatment (e) is carried out so that the Young's modulus of the adhesive layer after irradiation and heat treatment is between 0.05 GPa and 10 GPa, the Young's modulus being measured by nanoindentation;
the heat treatment (e) comprises the application of a temperature of between 90° C. and 110° C., for a duration of between 1 hour and 12 hours, in a dinitrogen atmosphere;
the light flux is applied through the piezoelectric substrate;
the light flux has a wavelength of between 200 nm and 500 nm;
the thickness of the photopolymerizable adhesive layer is between 1 μm and 50 μm and the irradiation energy received by the adhesive layer during the irradiation step is between 0.7 J/cm² and 10 J/cm²;
the photopolymerizable adhesive layer is deposited by spin coating;
the photopolymerizable adhesive layer comprises an isocyanurate, acrylate or epoxy adhesive that can be crosslinked by ultraviolet radiation with or without a hardening agent;
the bonding step is carried out at a temperature between 10° C. and 50° C. and/or whereby the irradiation step is carried out at a temperature of between 10° C. and 50° C.

The present disclosure also relates to a process for transferring a piezoelectric layer onto a carrier substrate, comprising:
forming a donor substrate by implementing the process for fabricating a donor substrate as described above,
forming a weakened zone in the thinned piezoelectric substrate, so as to delimit the piezoelectric layer to be transferred,
providing the carrier substrate,
bonding the donor substrate to the carrier substrate, the piezoelectric layer to be transferred being located at the bonding interface, and
detaching the donor substrate along the weakened zone so as to transfer the piezoelectric layer to be transferred to the carrier substrate.

According to other optional features of the process for transferring a piezoelectric layer onto a carrier substrate, taken alone or in combination when this is technically possible:
the process comprises, prior to bonding, the formation of an oxide layer, or a nitride layer, or a layer comprising a combination of nitride and oxide, or a superposition of at least one oxide layer and one nitride layer on the carrier substrate;
the weakened zone is formed by implanting atomic species into the piezoelectric substrate; and
the handle substrate and the carrier substrate are fabricated from materials such that the difference in thermal expansion coefficient between the material of the handle substrate and the carrier substrate is less than or equal to 5%, and preferably approximately equal to 0%.

The present disclosure also relates to a process for fabricating a bulk acoustic wave device comprising the deposition of electrodes on two opposite faces of a piezoelectric layer, wherein it comprises the fabrication of the piezoelectric layer by a process for transferring a piezoelectric layer onto a carrier substrate as described above.

The present disclosure finally relates to a donor substrate for the transfer of a piezoelectric layer, consisting of a heterostructure comprising a piezoelectric substrate bonded to a handle substrate, wherein the substrate comprises, at the interface between the piezoelectric substrate and the handle substrate, a polymerized adhesive layer having a Young's modulus of between 0.05 GPa and 10 GPa.

According to other optional features of the donor substrate for the transfer of a piezoelectric layer, taken alone or in combination when this is technically possible:
the thickness of the polymerized adhesive layer is between 1 μm and 50 μm;
the polymerized adhesive layer comprises an isocyanurate, acrylate or epoxy adhesive that can be crosslinked by ultraviolet radiation with or without a hardening agent.

### BRIEF DESCRIPTION OF THE DRAWINGS

Other features and advantages of the present disclosure will become apparent from the following detailed description, with reference to the appended drawings, in which:

FIG. 1A represents a topology profile produced using a mechanical profilometer and showing the undulations present on the free surface of a donor substrate that has been subjected to a heat treatment according to one embodiment of the present disclosure, and FIG. 1B represents a topology profile produced using a mechanical profilometer and showing the undulations present on the free surface of a fabricated donor substrate that has not been subjected to the heat treatment (the profiles are presented on the same scale);

FIG. 2 represents a cross-sectional view of a donor substrate fabricated according to one embodiment of the process according to the present disclosure comprising, from its back face to its front face: a handle substrate, a photopolymerized adhesive layer and a thinned piezoelectric layer;

FIG. 3 represents a cross-sectional view of a handle substrate and of a piezoelectric substrate provided for the implementation of the process of the present disclosure;

FIG. 4 represents a cross-sectional view of a step of depositing a photopolymerizable adhesive layer on the handle substrate according to one embodiment of the process according to the present disclosure;

FIG. 5 represents a cross-sectional view of the multilayer structure obtained after a step of bonding the piezoelectric substrate and the handle substrate by means of a photopolymerizable adhesive layer according to one embodiment of the process according to the present disclosure;

FIG. 6 represents a cross-sectional view of a step of irradiating the multilayer structure from FIG. 5;

FIG. 7 represents a cross-sectional view of the multilayer structure obtained after irradiation and then heat treatment of the structure represented in FIG. 5 according to one embodiment of the process according to the present disclosure;

FIG. 8 represents a cross-sectional view of a step of thinning the piezoelectric substrate in the multilayer structure from FIG. 7 according to one embodiment of the process according to the present disclosure;

FIG. 9 represents a cross-sectional view of the carrier substrate for the transfer of a piezoelectric layer to be transferred;

FIG. 10 represents a cross-sectional view of a step of forming a weakened zone within the thinned piezoelectric layer by implanting atomic species so as to delimit a piezoelectric layer to be transferred according to one embodiment of the process for transferring a piezoelectric layer onto a carrier substrate according to the present disclosure;

FIG. 11 represents a cross-sectional view of a step of bonding the implanted carrier substrate from FIG. 10 to the carrier substrate from FIG. 9, the piezoelectric layer to be transferred being at the interface;

FIG. 12 represents a cross-sectional view of the multilayer structure obtained after transferring the piezoelectric layer to be transferred onto the carrier substrate by detachment along the weakened zone;

FIG. 13 represents a cross-sectional view of a bulk acoustic wave device.

For the sake of legibility, the drawings have not necessarily been drawn to scale.

### DETAILED DESCRIPTION

The present disclosure relates to a process for fabricating a pseudo-donor substrate for transferring a piezoelectric layer onto a carrier substrate, the pseudo-donor substrate being formed by joining a thick piezoelectric layer and a handle substrate by means of a photopolymerized adhesive layer and then thinning the thick piezoelectric layer, for example, by grinding.

The multilayer structures resulting from the transfer of the piezoelectric layer from such a pseudo-donor substrate to a carrier substrate have many voids at their periphery, at their bonding interface, which reduce the quality of bonding between the active layer transferred and the receiver substrate.

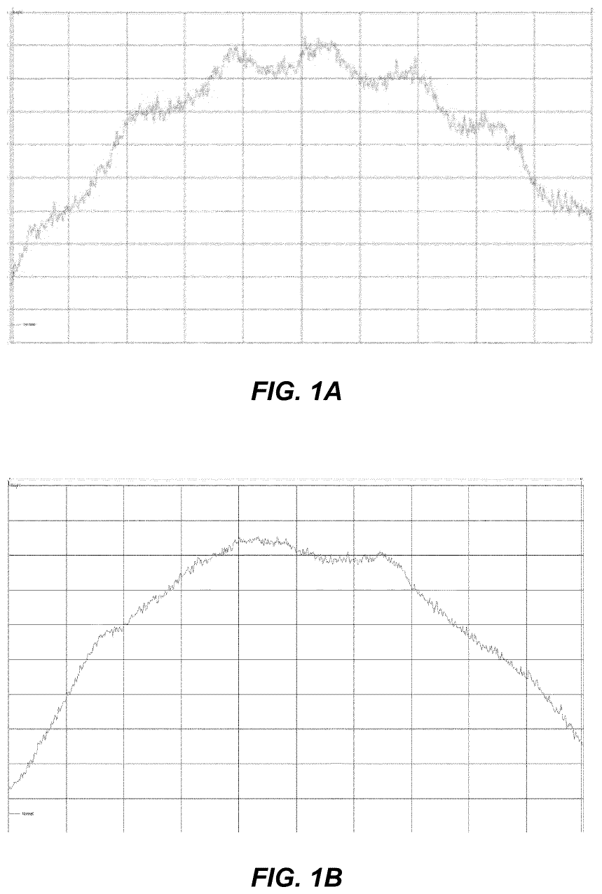

Following the step of thinning the thick piezoelectric layer, it was observed that the free surface of the thinned piezoelectric layer of the pseudo-donor substrate has, at the periphery and over a width of around 5 mm, a relief in the form of peaks and troughs (waviness seen in FIG. 1A).

It is hypothesized that it is this peripheral relief that generates the voids in the final multilayer structure.

Furthermore, it is assumed that this relief in the form of peaks and troughs is formed owing to the thick piezoelectric layer going into resonance under the effect of the vibrations generated by the thinning process, and note that this relief is even more marked when the mechanical strength of the piezoelectric layer-handle substrate assembly is poor.

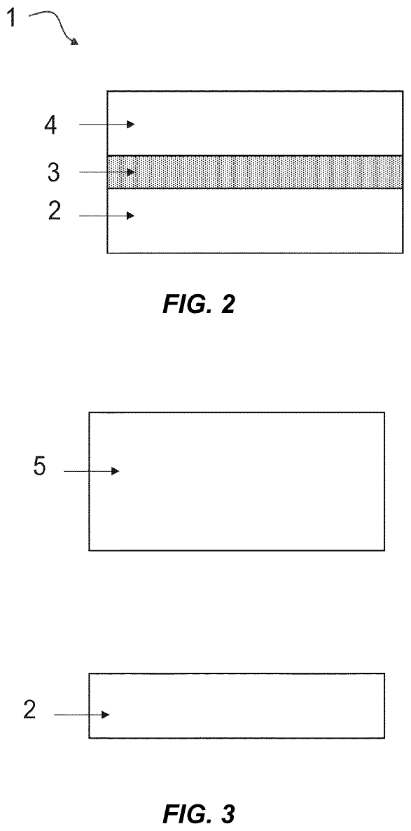

To this end, the present disclosure relates to a process for fabricating a donor substrate for the transfer of a piezoelectric layer to a carrier substrate. An example of a donor substrate 1 according to the present disclosure is represented in FIG. 2. The donor substrate 1 has a multilayer structure comprising, from its back face to its front face:
a handle substrate 2,
a photopolymerized adhesive layer 3, and
a thinned piezoelectric substrate 4.

By way of example, the thinned piezoelectric substrate 4 is fabricated from a material such as lithium tantalate (LiTaO₃), lithium niobate (LiNbO₃), barium titanate (BaTiO₃) and/or lead zirconate titanate (PZT). The piezoelectric layer 4 has a thickness of between 50 nm and 20 μm, preferably a thickness of between 100 nm and 10 μm.

The piezoelectric material of the piezoelectric substrate 4 and the material of the carrier substrate have very different thermal expansion coefficients. The deposition of a layer of piezoelectric material without a handle substrate on the carrier substrate would expose the resulting multilayer structure to considerable deformation when carrying out thermal anneals, for example, to strengthen the bonding interface between the layer of piezoelectric material and the carrier substrate.

The handle substrate 2 is thus preferentially fabricated from a material having a thermal expansion coefficient similar to that of the material of the carrier substrate to which the thinned piezoelectric layer 4 is intended to be bonded. The term “similar” is understood to mean a difference in thermal expansion coefficient between the material of the handle substrate 2 and the material of the carrier substrate of less than or equal to 5%, and preferably equal to or close to 0%. Suitable materials are, for example, silicon, sapphire, polycrystalline aluminum nitride, or gallium arsenide. Preferentially, the handle substrate 2 is fabricated from the same material as the carrier substrate. In the present disclosure, it is the thermal expansion coefficient in a plane parallel to the main surface of the substrates that is of interest. The handle substrate 2 has a thickness of between 100 μm and 2 mm, preferentially a thickness of between 200 μm and 1 mm. Preferentially, the handle substrate 2 has a thickness similar to that of the carrier substrate, so that the structure obtained after bonding of the donor substrate to the carrier substrate is as symmetrical as possible and as balanced as possible in terms of mechanical and thermal behavior. A thermal expansion coefficient and a thickness of the handle substrate 2 that are similar to the thermal expansion coefficient and the thickness, respectively, of the carrier substrate make it possible to minimize the stresses on the multilayer structure and its deformation under the effect of temperature fluctuations.

With reference to FIG. 3, the process for fabricating the donor substrate comprises providing a piezoelectric substrate 5 and the handle substrate 2.

The piezoelectric substrate 5 has a thickness of between 100 μm and 2 mm, preferentially a thickness of between 200 μm and 1 mm. The piezoelectric substrate 5 is formed of the piezoelectric material, which constitutes the thinned piezoelectric layer 4 in the final multilayer structure. The piezoelectric substrate 5 may thus comprise LiTaO₃, LiNbO₃, BaTiO₃ and/or PZT.

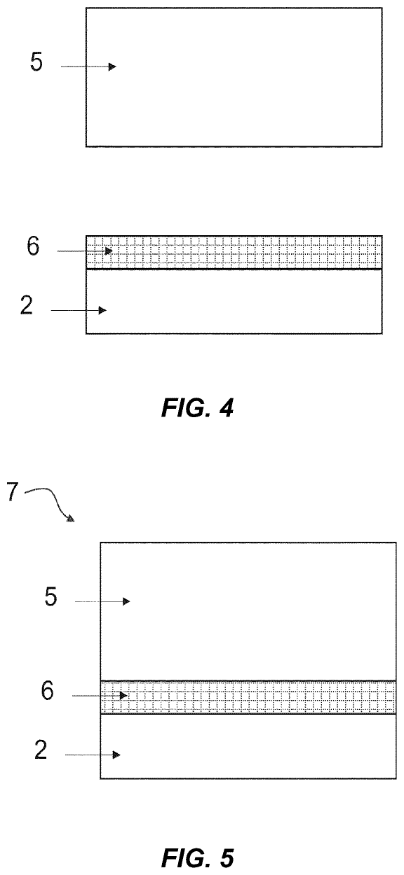

The process for fabricating the donor substrate according to the present disclosure further comprises the deposition of a photopolymerizable adhesive layer 6 on a main face of the handle substrate 2 or of the piezoelectric substrate 5. By way of example, FIG. 4 shows a particular embodiment in which the photopolymerizable adhesive layer 6 is deposited on the handle substrate 2.

The photopolymerizable adhesive layer is advantageously deposited by spin coating.

This technique consists in rotating the substrate on which the photopolymerizable layer is to be deposited on itself at a substantially constant and relatively high speed in order to spread the photopolymerizable layer uniformly over the entire surface of the substrate by centrifugal force. To this end, the substrate is typically placed and held by vacuum chuck on a turntable. A person skilled in the art is capable of determining the operating conditions, such as the volume of adhesive deposited on the surface of the substrate, the speed of rotation of the substrate, and the minimum deposition time according to the desired thickness for the adhesive layer. Deposition by spin coating advantageously enables the uniformity of the thickness of the photopolymerizable adhesive layer deposited to be well controlled. The thickness of the photopolymerizable adhesive layer deposited is typically between 1 μm and 50 μm. A thickness of less than 1 μm is unattainable with an excessively viscous photopolymerizable adhesive layer. Furthermore, below a thickness of less than 1 μm, there are risks that in certain zones, the thickness of the photopolymerizable adhesive layer will be almost zero. A thickness of greater than 50 μm is unattainable with an excessively liquid photopolymerizable adhesive layer. In addition, since the photopolymerized polymer is softer than the other layers, a thickness of greater than 50 μm risks adversely affecting the good mechanical strength of the donor substrate.

The photopolymerizable adhesive layer 6 preferentially comprises an isocyanurate, acrylate or epoxy adhesive that can be crosslinked by ultraviolet radiation with or without a hardening agent. For example, the photopolymerizable adhesive layer 6 comprises two isocyanurate-type monomers and a thiol derivative. Such an adhesive has the advantage of being polymerizable at wavelengths to which the piezoelectric material is at least partially transparent. In addition, it exhibits good temperature resistance up to 250° C.

Bonding by a photopolymerizable adhesive layer has the advantage of including fewer fabrication steps than molecular bonding. It is therefore simple to implement and inexpensive. In addition, the photopolymerized adhesive layer gives the pseudo-donor substrate good mechanical strength without requiring a high-temperature thermal anneal, which would be liable to cause significant bowing of the substrate, which is not the case with molecular bonding. Lastly, the polymer, which is initially liquid, will smooth over flatness defects and partially compensate for the lower edge resulting from chamfering of the substrates. Bonding by a photopolymerizable adhesive layer thus makes it possible to bond the substrates closer to their edge.

With reference to FIG. 5, after the deposition of the photopolymerizable adhesive layer on a main face of the handle substrate 2 or of the piezoelectric substrate 5, the piezoelectric substrate 5 is bonded with the handle substrate 2 via the photopolymerizable adhesive layer 6 to form a heterostructure 7. The bonding is preferably carried out at ambient temperature, i.e., at about 20° C. It is however possible to carry out the bonding at a temperature of between 10° C. and 50° C., and more preferably between 20° C. and 30° C., more preferentially at a temperature close to ambient temperature. Indeed, the further the bonding temperature is from ambient temperature, the more the heterostructure 7 will deform when it returns to its equilibrium temperature. In addition, the bonding step is advantageously carried out under vacuum, which makes it possible to desorb water from the surfaces forming the bonding interface, i.e., the surface of the adhesive layer and the surface of the handle substrate or of the piezoelectric substrate.

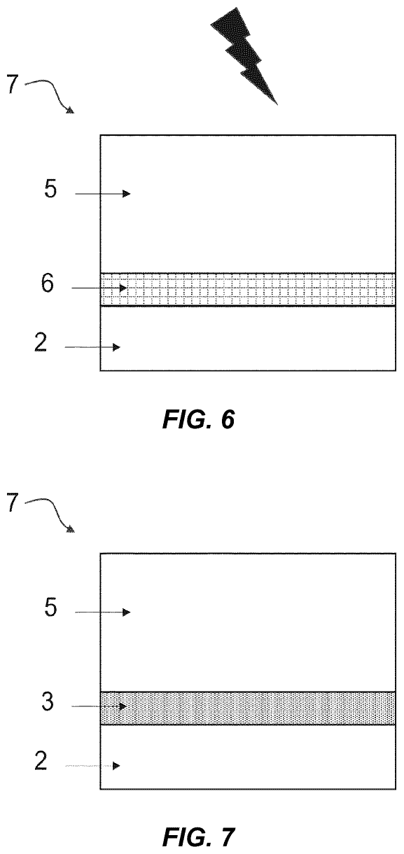

Then, with reference to FIG. 6, the heterostructure 7 is irradiated by a light flux in order to polymerize the adhesive layer.

For example, the light flux may be applied through the piezoelectric substrate 5 if the piezoelectric substrate 5 is at least partially transparent in the wavelength range that makes it possible to initiate the polymerization of the photopolymerizable adhesive layer 6. As a further example, the light flux is applied through the piezoelectric substrate 5 if the piezoelectric substrate 5 is at least partially transparent in the wavelength range that makes it possible to initiate the polymerization of the photopolymerizable adhesive layer 6.

The irradiation is preferentially carried out at a temperature of between 10° C. and 50° C., more preferentially at a temperature close to ambient temperature. Indeed, the further the temperature is from ambient temperature, the more the heterostructure 7 will deform when it returns to its equilibrium temperature.

The irradiation energy received by the photopolymerizable adhesive layer 6 is advantageously between 0.7 J/cm² and 10 J/cm². In the case where the irradiation of the photopolymerizable adhesive layer 6 is carried out through the handle substrate 2 or through the piezoelectric substrate 5, it is advisable to take into account the absorption coefficient at the irradiation wavelength and the thickness of the material passed through in order to determine the irradiation power actually received by the photopolymerizable adhesive layer 6.

The wavelength of the incident light flux is chosen as a function of the nature of the photopolymerizable adhesive layer 6 and of the material through which the incident light flux passes (handle substrate 2 or piezoelectric substrate 5). Indeed, the photopolymerizable adhesive layer 6 must absorb at the wavelength and the absorption must initiate the polymerization. Furthermore, the material passed through by the incident light flux must not be completely absorbed by the material passed through, such that it would not be possible to irradiate the photopolymerizable adhesive layer 6 with the necessary power. Preferentially, the light flux has a wavelength of between 200 nm and 500 nm. Indeed, it is in this wavelength range that the piezoelectric substrate is advantageously the most transparent.

Irradiation of the heterostructure 7 comprising the thick piezoelectric layer 5, the photopolymerizable adhesive layer 6 and the handle substrate 2 makes it possible to initiate the chain polymerization reaction of the monomer. It is assumed that the polymer chains grow until the steric hindrance is greater than the thermal motion, and prevents the active sites from coming together, thus blocking the polymerization reaction. The steric hindrance thus limits the degree of crosslinking of the polymer chains, and therefore the stiffness of the photopolymerized adhesive layer, which can be attained by simple irradiation of the heterostructure.

After irradiation of the heterostructure by a light flux, the process according to the present disclosure comprises an additional step of heat treatment of the irradiated heterostructure, so as to obtain the photopolymerized adhesive layer 3 as shown in FIG. 7.

The heat treatment according to the present disclosure of the irradiated heterostructure prior to thinning of the thick piezoelectric layer makes it possible to increase the thermal motion within the adhesive layer and to reconnect active sites on the polymer chains so as to continue the crosslinking of the polymer initiated by the irradiation. The heat treatment therefore makes it possible to attain a degree of crosslinking of the polymer greater than that attainable by simple irradiation, irrespective of the irradiation dose used, and thus a greater stiffness of the photopolymerized adhesive layer. The pseudo-donor substrate thus has better mechanical strength and less sensitivity to the vibrations of the thinning process: the free surface of the pseudo-donor substrate is flatter on conclusion of the thinning step.

The heat treatment of the previously irradiated heterostructure is preferentially carried out so that the Young's modulus of the adhesive layer after irradiation and heat treatment is between 0.05 GPa and 10 GPa, preferentially between 3.5 GPa and 10 GPa.

The Young's modulus is measured by nanoindentation: a tip of calibrated shape and size made of a hard material, for example, a diamond tip, is applied with a force of a given intensity to the surface of the material for which it is desired to evaluate the Young's modulus. The Young's modulus is then evaluated as a function of the size of the impression left in the material.

The nanoindentation for measuring the Young's modulus of the photopolymerized adhesive layer 3 is performed on a multilayer structure comprising a test photopolymerized adhesive layer deposited on a handle substrate without a thick piezoelectric layer (or conversely on a thick piezoelectric substrate without a handle substrate), the test photopolymerized adhesive layer having been prepared under the same conditions as the photopolymerized adhesive layer 6. More specifically, the preparation of the test photopolymerized adhesive layer comprises deposition of a test photopolymerizable adhesive layer and irradiation and then heat treatment of the deposited test photopolymerizable adhesive layer, the deposition irradiation and heat treatment conditions applied to the test photopolymerizable adhesive layer being identical to those applied to the photopolymerizable adhesive layer 6. Identical irradiation conditions are understood to mean that the irradiation power received by the test photopolymerizable adhesive layer is identical to the irradiation power received by the photopolymerizable adhesive layer 6. Since the irradiation of the photopolymerizable adhesive layer 6 is carried out through the handle substrate 2 or through the piezoelectric substrate 5, the absorption coefficient at the irradiation wavelength and the thickness of the material passed through should be taken into account in order to determine the irradiation power to be applied to the test photopolymerizable adhesive layer.

A Young's modulus of the photopolymerized adhesive layer of between 0.05 GPa and 10 GPa advantageously makes it possible to reduce the number of voids or “edge bonding voids” at the bonding interface between the donor substrate comprising such a photopolymerized adhesive layer 3 and a carrier substrate. For example, a Young's modulus of the photopolymerized adhesive layer 3 of greater than 3.5 GPa makes it possible to divide the number of voids or “edge bonding voids” by five with respect to a bonding interface between a carrier substrate and a donor substrate comprising a photopolymerized adhesive layer that has not been subjected to the heat treatment according to the present disclosure.

A simple irradiation of the heterostructure 7 does not make it possible to attain a Young's modulus of greater than 3.5 GPa, even by increasing the irradiation power received to 400 mW. Furthermore, too great an increase in the irradiation power, owing to the fact that the piezoelectric substrate 5 absorbs a portion of the insolation, gives rise to a large risk of deformation of the piezoelectric substrate 5.

According to one particularly advantageous embodiment of the heat treatment of the irradiated heterostructure, the heat treatment comprises the application to the heterostructure of a temperature of between 90° C. and 110° C. for a duration of between 1 hour and 12 hours, preferentially between 1 hour and 5 hours, more preferentially between 1 hour and 3 hours in a dinitrogen atmosphere. Such a temperature range advantageously makes it possible to obtain a Young's modulus of the photopolymerized adhesive layer of greater than 3 GPa after 3 hours, and a maximum Young's modulus of the order of 10 GPa after 5 hours. Such durations advantageously make it possible to keep a reasonable process time for the volume production of wafers.

A temperature below 110° C. advantageously makes it possible to avoid the risk of deformation of the structure owing to the very different thermal expansion coefficients between the piezoelectric substrate 5 and the handle substrate 2.

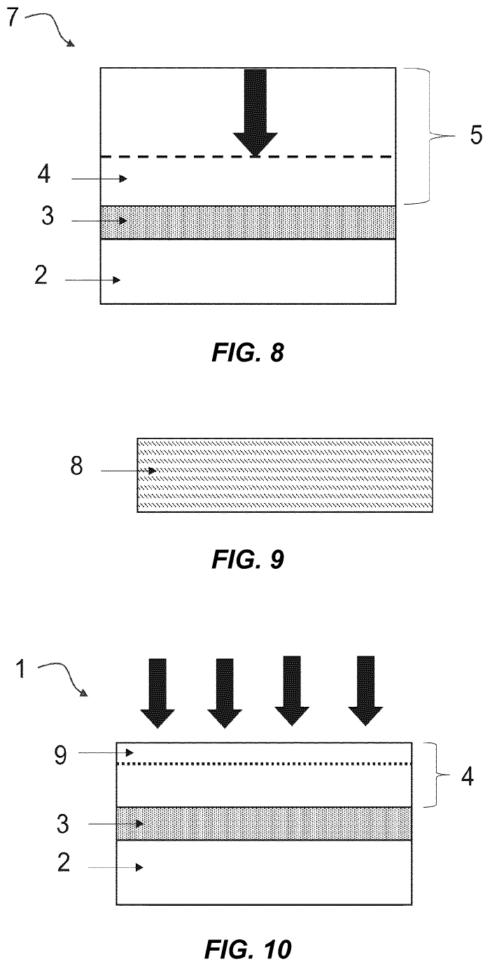

After heat treatment of the heterostructure 7, the piezoelectric layer 5 is thinned from the side thereof opposite the handle substrate, as shown in FIG. 8, so that the thinned piezoelectric layer 4 has a thickness of between 1 μm and 100 μm, preferentially a thickness of between 5 μm and 50 μm.

Thinning of the handle substrate 2 is, for example, carried out by coarse grinding, which makes it possible to rapidly reduce the thickness of the heterostructure. Next, finer grinding may be implemented to continue reducing the thickness of the heterostructure, while decreasing the roughness of the surface of the final donor substrate 1.

Lastly, chemical mechanical polishing (CMP) can be carried out to smooth the free surface of the thinned piezoelectric layer 4 opposite the handle substrate 2, so as to attain the desired roughness for bonding of the donor substrate 1 to the carrier substrate 8 and thus improve the quality of bonding.

Supplementing the irradiation of the photopolymerizable adhesive layer 6 with a heat treatment according to the process of the present disclosure advantageously makes it possible to increase the mechanical strength of the donor substrate. The better mechanical strength of the donor substrate provides the donor substrate with better resistance to the vibrations generated by the grinding and polishing steps, so that the relief observed at the periphery of the thinned piezoelectric layer made up of peaks and troughs is much less pronounced. Thus, the free surface of the thinned piezoelectric layer is flatter at the edge of the wafer, which allows a better quality bonding of the donor substrate to the carrier substrate. FIG. 1B shows the topology profile produced with the aid of a mechanical profilometer on the free surface of a donor substrate that has undergone the heat treatment according to one embodiment of the present disclosure. The amplitude of the undulations is therefore reduced in comparison with the profile of FIG. 1A representing the topology profile on the free surface of a donor substrate that has not undergone the heat treatment.

The present disclosure also relates to a process for transferring a piezoelectric layer onto a carrier substrate.

A donor substrate comprising the piezoelectric layer to be transferred is initially provided. The donor substrate is preferably obtained via the fabrication process described above according to the first subject of the present disclosure.

With reference to FIG. 9, a carrier substrate 8 capable of receiving the piezoelectric layer to be transferred is also provided.

Preferentially, the handle substrate 2 and the carrier substrate 8 are fabricated from materials such that the difference in thermal expansion coefficient between the material of the handle substrate 2 and the carrier substrate 8 is less than or equal to 5%, and preferably approximately equal to 0%.

A weakened zone is formed in the thinned piezoelectric substrate 4 so as to delimit a piezoelectric layer to be transferred 9. The depth of the weakened zone relative to the exposed surface of the thinned piezoelectric substrate 4 determines the thickness of the piezoelectric layer to be transferred 9.

According to one preferred embodiment shown in FIG. 10, the weakened zone is formed by implanting atomic species into the thinned piezoelectric substrate, the implantation being shown in FIG. 10 by the black arrows. The atomic species are implanted at a determined depth of the thinned piezoelectric substrate 4, which determines the thickness of the piezoelectric layer to be transferred 9.

When the weakened zone is formed by implanting atomic species, the implanted atomic species are preferably hydrogen ions and/or helium ions.

According to one embodiment, an oxide layer, or a nitride layer, or a layer comprising a combination of nitride and oxide, or a superposition of at least one oxide layer and one nitride layer is then formed on the carrier substrate (not shown). Such an oxide or nitride layer or layer comprising a combination of nitride and oxide advantageously makes it possible to improve the bonding energy between the two substrates.

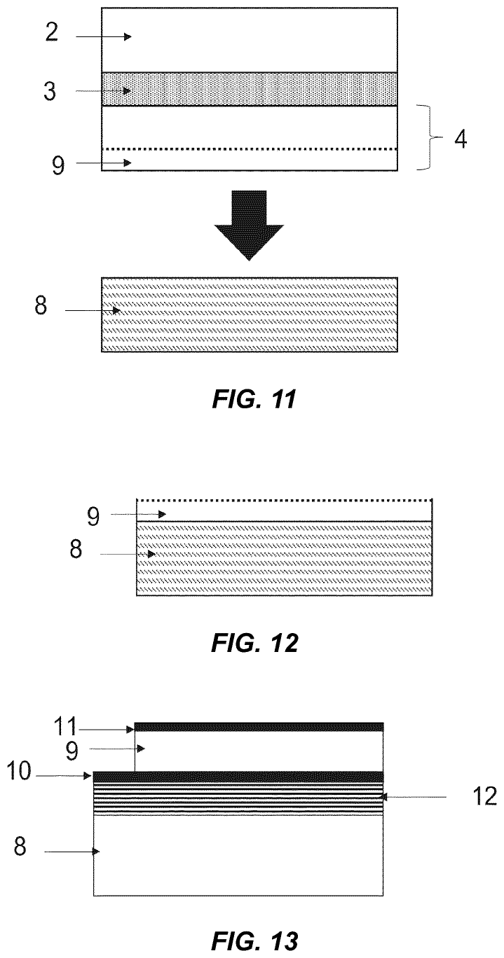

With reference to FIG. 11, the donor substrate is then bonded to the carrier substrate 8, the piezoelectric layer to be transferred 9 and the optional dielectric layer being located at the bonding interface.

The multilayer structure formed then comprises successively, from a back face to a front face, the carrier substrate 8, the optional dielectric layer, the thinned piezoelectric substrate 4, the photopolymerized layer 3 and the handle substrate 2.

The multilayer structure formed has few voids at the periphery of the structure at the bonding interface between the donor substrate and the carrier substrate, (“edge bonding voids”), the detection of the voids being carried out by laser detection. Such an effect is advantageously obtained because the donor substrate according to the present disclosure has a very low relief on the free surface of the thinned piezoelectric layer prior to the bonding of the donor substrate with the carrier substrate.

With reference to FIG. 12, the donor substrate is then detached along the weakened zone in order to transfer the piezoelectric layer to be transferred 9 onto the carrier substrate 8.

The detachment along the weakened zone may be triggered by a mechanical action and/or a supply of thermal energy. The supply of thermal energy may comprise an anneal in a furnace at a temperature of between 150° C. and 300° C., preferentially between 150° C. and 220° C. in order to avoid degradation of the polymer.

Finally, owing to a small number of voids at the bonding interface between the donor substrate and the piezoelectric layer, a better transfer of the piezoelectric layer to the carrier substrate at the wafer edge is obtained.

The present disclosure extends to a process for fabricating a bulk acoustic wave device comprising the deposition of electrodes on two opposite faces of a piezoelectric layer, wherein it comprises the fabrication of the piezoelectric layer by a process for transferring the piezoelectric layer onto a carrier substrate according to any one of the embodiments described above.

More specifically, before bonding the piezoelectric layer to be transferred 9 from the donor substrate to the carrier substrate 8, a first electrode is deposited on the free surface of the layer 9, this first electrode (reference 10 in FIG. 13) being buried in the final stack. After the step of transferring the piezoelectric layer 9 from the donor substrate to the carrier substrate 8, a second electrode (reference 11 in FIG. 13) is deposited on the free surface of the layer 9, opposite the first electrode. To prevent the propagation of the acoustic waves into the carrier substrate 8, it is possible to integrate therewithin an isolation means that may be, for example, a Bragg mirror 12 (as illustrated in FIG. 13) or a cavity previously etched into the carrier substrate 8.

1. A method of fabricating a donor substrate for transferring a piezoelectric layer to a carrier substrate, comprising the following successive steps:
(a) providing a piezoelectric substrate and a handle, substrate;
(b) depositing a photopolymerizable adhesive layer on a main face of the handle substrate or of the piezoelectric substrate;
(c) bonding the piezoelectric substrate with the handle substrate via the adhesive layer to form a heterostructure;
(d) irradiating the heterostructure with a light flux to polymerize the adhesive layer;
(e) heat treating the irradiated heterostructure; and
(f) thinning the piezoelectric substrate from the side thereof opposite the handle substrate so as to form the donor substrate.

2. The method of claim 1, further comprising a step (g) of chemical-mechanical polishing of free surface of the thinned piezoelectric substrate.

3. The method of claim 1, wherein the heat treatment (e) is carried out so as to increase a degree of crosslinking of the polymer in the photopolymerized adhesive layer and/or the stiffness of the photopolymerized adhesive layer.

4. The method of claim 1, wherein the heat treatment (e) is carried out so that the Young's modulus of the adhesive layer after irradiation and heat treatment is between 3.5 GPa and 10 GPa, the Young's modulus being measured by nanoindentation.

5. The method of claim 1, wherein the heat treatment (e) comprises application of a temperature of between 90° C. and 110° C., for a duration of between 1 hour and 12 hours, in a dinitrogen atmosphere.

6. The method of claim 1, wherein the light flux is applied through the piezoelectric substrate.

7. The method of claim 1, wherein the light flux has a wavelength between 200 nm and 500 nm.

8. The method of claim 1, wherein the thickness of the photopolymerizable adhesive layer is between 1 μm and 50 μm and the irradiation energy received by the adhesive layer during the irradiation step is between 0.7 J/cm² and 10 J/cm².

9. The method of claim 1, wherein the photopolymerizable adhesive layer is deposited by spin coating.

10. The method of claim 1, wherein the photopolymerizable adhesive layer comprises an isocyanurate, acrylate or epoxy adhesive that can be crosslinked by ultraviolet radiation with or without a hardening agent.

11. The method of claim 1, wherein the bonding step (c) is carried out at a temperature between 10° C. and 50° C. and/or wherein the irradiation step (d) is carried out at a temperature of between 10° C. and 50° C.

12. A method of transferring a piezoelectric layer onto a carrier substrate, comprising:
forming a donor substrate by implementing method according to claim 1;
forming a weakened zone in the thinned piezoelectric substrate, so as to delimit the piezoelectric layer to be transferred;
providing the carrier substrate;
bonding the donor substrate to the carrier substrate the piezoelectric layer to be transferred being located at the bonding interface; and
detaching the donor substrate along the weakened zone to transfer the piezoelectric layer to be transferred to the carrier substrate.

13. The method of claim 12, further comprising, prior to bonding the donor substrate to the carrier substrate, forming an oxide layer, or a nitride layer, or a layer comprising a combination of nitride and oxide, or a superposition of at least one oxide layer and one nitride layer on the carrier substrate.

14. The method of claim 12, wherein the forming of the weakened zone comprises implanting atomic species into the thinned piezoelectric substrate.

15. The method of claim 12, wherein the handle substrate and the carrier substrate are fabricated from materials such that a difference in thermal expansion coefficient between the material of the handle substrate and the material of the carrier substrate is less than or equal to 5%.

16. A method of fabricating a bulk acoustic wave device comprising fabricating a piezoelectric layer by a process according to claim 12 and depositing electrodes on two opposite faces of the piezoelectric layer.

17. A donor substrate for the transfer of a piezoelectric layer, comprising a heterostructure including a piezoelectric substrate bonded to a handle substrate, wherein the donor substrate comprises, at an interface between the piezoelectric substrate and the handle substrate, a polymerized adhesive layer having a Young's modulus of between 3.5 GPa and 10 GPa.

18. The donor substrate of claim 17, wherein thickness of the polymerized adhesive layer is between 1 μm and 50 μm.

19. The donor substrate of claim 17, wherein the polymerized adhesive layer comprises an isocyanurate, acrylate or epoxy adhesive that can be crosslinked by ultraviolet radiation with or without a hardening agent.

20. The method of claim 15, wherein the handle substrate and the carrier substrate are fabricated from materials such that the difference in thermal expansion coefficient between the material of the handle substrate and the material of the carrier substrate is 0%.
